(19) United States
(12) Patent Application Publication
(10) Pub. No.: US 2015/0116924 A1
(43) Pub. Date: Apr. 30, 2015

(54) MOUNTING DEVICE FOR HARD DISK DRIVE

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: CHIEN-MIN HUNG, New Taipei (TW); CHING-JOU CHEN, New Taipei (TW)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/078,450

(22) Filed: Nov. 12, 2013

(30) Foreign Application Priority Data
Oct. 28, 2013 (TW) 102138846

(51) Int. Cl. H05K 7/18

(52) U.S. Cl. CPC H05K 7/183
USPC 361/679.33

(57) ABSTRACT

A mounting device for mounting a hard disk drive (HDD) includes a frame and a fixing member. The frame includes two side boards and a connecting board connected between the side boards. Each side board defines a latching hole and a positioning hole. The fixing member includes two arms fixed to opposite sides of the HDD and a resilient handle connected between the arms. Two latching portions extend from opposite ends of the handle to be detachably engaged in the latching holes. A protrusion protrudes from each arm to be detachably inserted into a corresponding one of the positioning holes. The handle can be pulled away from the connecting board to disengage the latching portions from the corresponding latching holes.

### BACKGROUND

1. Technical Field

The present disclosure relates to a mounting device for mounting a hard disk drive (HDD).

2. Description of Related Art

An electronic device, such as a computer, is generally equipped with a data storage device, such as a hard disk drive. Mounting the storage device to the electronic device by screws is inefficient, and always requires a tool, such as a screwdriver, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a mounting device, together with a hard disk drive.

FIG. 2 is an assembled, isometric view of FIG. 1.

FIG. 3 is similar to FIG. 2, but viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

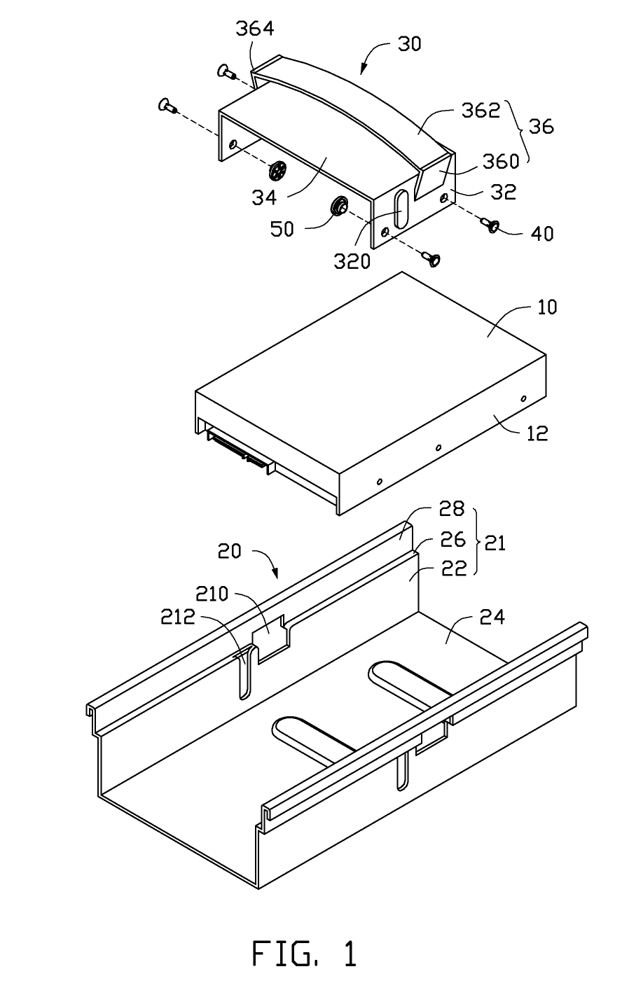

FIG. 1 shows an embodiment of a mounting device. The mounting device includes a frame 20 for receiving a hard disk drive (HDD) 10, a fixing member 30 is mounted to the frame 20.

The frame 20 includes two side boards 21 and a connecting board 24 connected between bottom sides of the side boards 21. Each side board 21 includes a main board 22 perpendicularly connected to the connecting board 24, an extension piece 26 perpendicularly extending away from the other side board 21 from a top end of the main board 22, and a blocking piece 28 perpendicularly extending up from a side of the extension piece 26 opposite to the main board 22.

Each side board 21 defines a latching hole 210 and a positioning hole 212 adjacent to the latching hole 210. The latching hole 210 extends through an upper portion of the main board 22, the extension piece 26, and a lower portion of the blocking piece 28. The positioning hole 212 extends through the upper portion of the main board 22 and the extension piece 26.

The fixing member 30 includes two arms 32, a connecting bar 34 perpendicularly connected between top sides of the arms 32, and a resilient handle 36. The handle 36 includes two tabs 360 slantingly extending out and upward from upper portions of outer surfaces of the arms 32, and an arc-shaped holding portion 362 arced upward and connected between top sides of the tabs 360. Therefore, two latching portions 364 protrude from junctions between the holding portion 364 and the tabs 364. A protrusion 320 protrudes from the outer surface of each arm 32 and is adjacent to the corresponding tab 360.

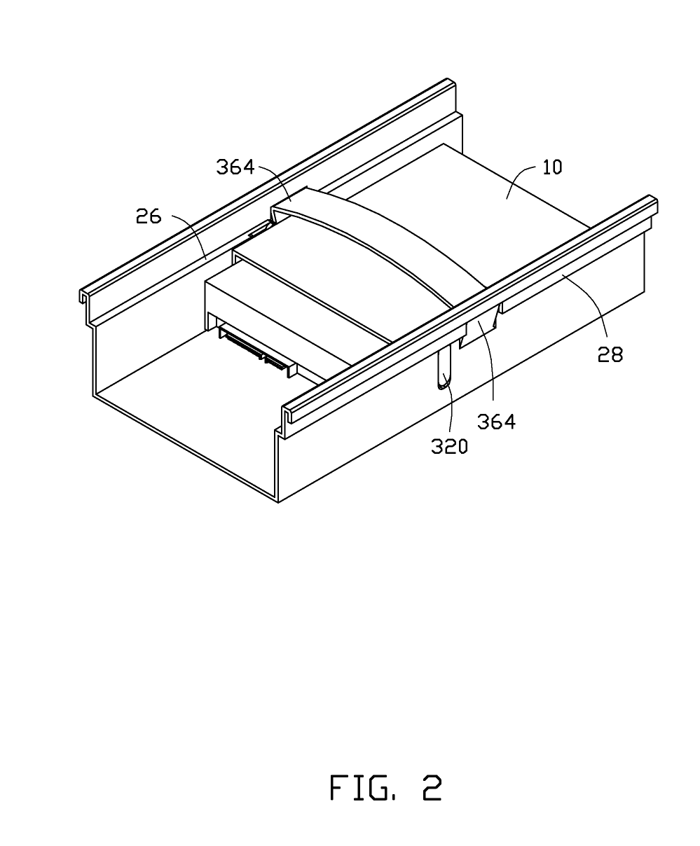

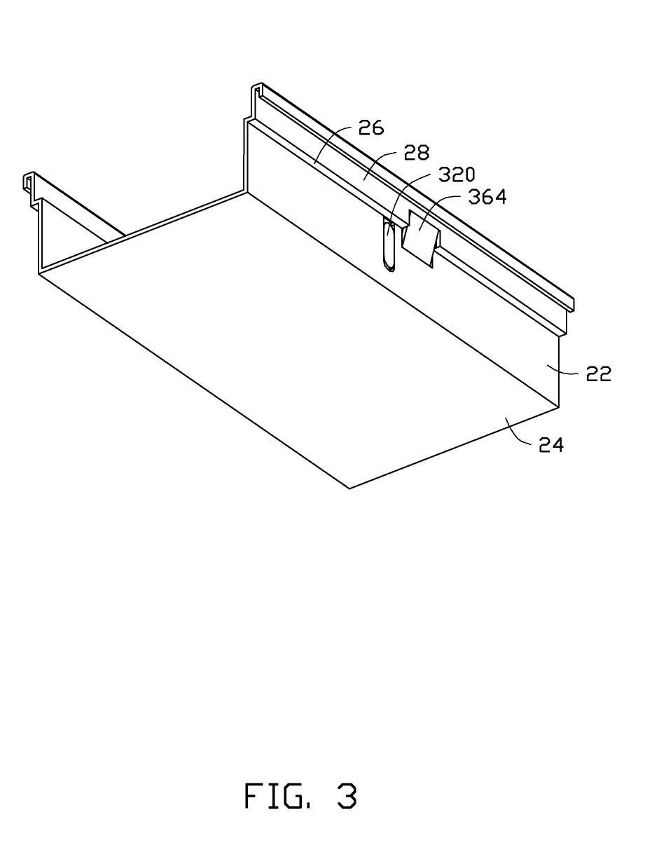

FIGS. 2 and 3 show that in assembly, the arms 32 are attached to sidewalls 12 of the HDD 10, and the connecting bar 34 is located above the HDD 10. Four screws 40 extend through the arms 32 and four shockproof members 50 and then are engaged in the sidewalls 12 of the HDD 10, to fix the fixing member 30 to the HDD 10.

The HDD 10 is mounted to the frame 20. The protrusions 320 align with the positioning holes 212. The HDD 10 is pressed into the frame 20, to insert the protrusion 320 into the positioning holes 212. The tabs 360 pass the corresponding blocking pieces 28 and are deformed toward each other, until the latching portions 364 align with the corresponding latching holes 210. The tabs 360 are restored, and the latching portions 364 are engaged in the latching holes 210 and are blocked by the corresponding blocking pieces 28, to fasten the HDD 10 in the frame 20.

The holding portion 362 can be pulled away from the connecting board 24 to deform the tabs 360 and disengage the latching portions 364 from the corresponding latching holes 210; thereby the HDD 10 can be slid out of the frame 20.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for mounting a hard disk drive (HDD), the mounting device comprising:
a frame comprising two side boards and a connecting board connected between bottom sides of the side boards; each side board defining a latching hole and a positioning hole; and
a fixing member comprising two arms to be fixed to opposite sides of the HDD and a resilient handle connected between the arms; two latching portions extending from opposite ends of the handle and detachably engaged in the latching holes, a protrusion protruding from each arm to be detachably inserted into a corresponding one of the positioning holes;
wherein the handle is operable to be pulled away from the connecting board to deform the handle to disengage the latching portions from the corresponding latching holes.

2. The mounting device of claim 1, wherein the fixing member further comprises a connecting bar connected between top sides of the arms.

3. The mounting device of claim 1, wherein the handle comprises two tabs slantingly extending out and upward from upper portions of the arms, and an arc-shaped holding portion connected between top sides of the tabs, the latching portions are formed at junctions between the holding portion and the tabs.

4. The mounting device of claim 1, wherein each side board includes a main board and an extension piece extending away from the other side board from a top side of the main board, the positioning hole extends through an upper portion of the main board and the extension piece.

5. The mounting device of claim 4, wherein each side board further comprises a blocking piece extending up from the extension piece, each latching hole extends through the upper portion of the corresponding main board and the corresponding extension piece, each latching portion is engaged in a corresponding one of the latching holes and is blocked by the corresponding blocking piece.
